(19) United States
(12) Patent Application Publication
(10) Pub. No.: US 2010/0028816 A1
(43) Pub. Date: Feb. 4, 2010

(54) PROCESS FOR PREPARING A POLYMERIC RELIEF STRUCTURE

(76) Inventors: Ko Hermans, Eindhoven (NL); Cornelis Wilhelmus Maria Bastiaansen, Eindhoven (NL); Dirk Broer, Eindhoven (NL); Jolke Perelaer, Eindhoven (NL)

Correspondence Address: NIXON & VANDERHYE, PC, 901 NORTH GLEBE ROAD, 11TH FLOOR, ARLINGTON, VA, 22203, US

(21) Appl. No.: 12/438,209

(22) PCT Filed: Aug. 28, 2007
(86) PCT No.: PCT/EP2007/007498

§ 371 Date: Jun. 22, 2009

(30) Foreign Application Priority Data
Aug. 30, 2006 (EP) 06018087.4

(51) Int. Cl. G03F 7/00

(52) U.S. Cl. 430/325

(57) ABSTRACT

The invention relates to a process for the preparation of a polymeric relief structure comprising the steps of coating a substrate with a coating composition comprising one or more radiation-sensitive ingredients, locally treating the coated substrate with electromagnetic radiation having a periodic or random radiation-intensity pattern, forming a latent image, and polymerizing and/or crosslinking the resulting coated substrate, wherein the coating composition comprises one or more radical scavengers in an amount sufficient to inhibit/retard substantial polymerization in the non-treated areas of the coated substrate, and low enough to allow polymerization and/or crosslinking in the treated areas in step c, with the proviso that the amount of oxygen present in the coating composition is not equal to the equilibrium amount of oxygen present when the coating composition is in contact with air.

The present invention relates to a process for the preparation of a polymeric relief and articles comprising the polymeric relief structure.

A process for the preparation of a polymeric relief structure, hereinafter also to be called ‘photo-embossing’ is known from “photo-embossing as a tool for complex surface relief structures” De Witz, Christiane; Broer, Dirk J., Abstracts of Papers, 226^{th} ACS National Meeting, New York, N.Y., United States, Sep. 7-11, 2003.

Such a process comprises the steps of
a) coating a substrate with a coating comprising one or more radiation-sensitive ingredients,
b) locally treating the coated substrate with electromagnetic radiation having a periodic or random radiation-intensity pattern, forming a latent image,
c) polymerizing and/or crosslinking the resulting coated substrate.

Polymers with a surface relief structure have a wide range of applications. For instance, such polymers in use in optical systems for data transport, storage and displays are nowadays of great interest. By structuring the surface of a polymer film or layer, light that passes these layers can be controlled. For instance if the surface structure contains small semi-sphere like elements a lens array is obtained that may focus transmitting light. Such an element is for instance useful in a backlight of a liquid crystal display to focus light on the transparent area of the display. For these types of applications it is often necessary to control the shape of the surface profiles down to the micrometer region. Also regular patterns of surface structures may diffract light such that a single beam, upon transmission, is split up in multiple beams that for instance can be used as beam splitter in telecommunication devices. Surface structures are also important to control reflection of light. This can successfully be applied to suppress specular reflection of a surface. This so-called anti-glare effect is for instance applied on the front screen of a television set. But also be used for applications such glazing, car finishes, etc. A polymer film, with well-defined surface profiles, may be provided with a conformal reflective film such as evaporated aluminum or sputtered silver. Incident light falling on this mirror is, upon reflection, distributed in space in a very controlled way. This is for instance used to make internal diffusive reflectors for reflective liquid crystal displays. Another application of surface profiles is for creating anti-fouling structures known as the Lotus effect. Thereto surface profiles with dimensions smaller than 1 micrometer are needed.

Electromagnetic-radiation induced polymerization, like UV photo-polymerization is a method to prepare devices from e.g. a mixture of two (meth)acrylate monomers and a photo-initiator. The polymerization reaction is initiated only in those regions where the UV light can activate the photo-initiator. In addition, it is possible to vary the light intensity spatially and vary the polymerization speed accordingly. Differences in the monomer reactivity, size or length, cross-linking ability, and energetic interaction result in gradients in the monomer chemical potentials. These chemical potentials form the driving force for monomer migration and for polymer swelling in the illuminated regions. The monomer diffusion coefficients determine the time-scale on which this migration takes place. Subsequently, uniform UV illumination with a higher intensity than during the patterned UV illumination is used to polymerize the entire film.

In specific cases, patterned UV photo-polymerization of a mixture of two liquid monomers results in a polymer relief structure. This can be done for example holographically or lithographically. Other methods to induce polymerization in a patterned way are based on writing with beams of electrons or ions. For holography, the interference pattern of two coherent light beams generates regions of high and low light intensity. For lithography, a photo-mask is used to produce these intensity differences. If for instance a striped mask is used, a grating is produced. If a mask with circular holes is used, a microlens structure is formed. Besides by creating a surface profile by material transport also refractive indices can be modulated. Differences in the refractive index are caused by lateral variations of monomer-unit concentrations in the polymer. Refractive index profile may further support the lens functions obtained from the surface geometries.

By using these techniques, it is possible to create phase and relief structures.

Alternative methods exist that make use of the diffusion of monomers after illumination of a resin composition, thereby generating structured materials. It is for example possible to design systems where the monomer migrates to the illuminated areas or away from it. Two mechanisms that describe the formation of the grating can be distinguished. Firstly, overall mass transport may occur, in which both monomers diffuse towards the illuminated regions. This is achieved by swelling of the growing polymer in the illuminated regions due to suction of monomers from the dark regions. This mechanism describes the formation of a relief grating. Secondly, if no swelling occurs, two-way diffusion, induced by differences in reactivity, describes the formation of a film with a flat surface, but a variation monomer unit concentration in the exposed and non-exposed areas. This mechanism describes the formation of a phase grating.

A better method is the photo-embossing process where a surface structure is created by using a resin composition that basically consists of a polymer, a monomer and an initiator. The polymer can be a single polymeric material but may also be a blend of more than one polymer. Similarly the monomer may be a single compound, but may also comprise several monomeric components. The initiator preferably is a photoinitiator that generates radicals upon exposure to UV-light. Alternatively, the photo-initiator generates cations upon exposure to UV light. The initiator may also be a mixture of a photoinitiator and a thermal initiator that generates radicals at elevated temperatures. This resin composition is generally dissolved in an organic solvent (giving a coating composition) in order to enhance processing, e.g. formation of thin films by spin coating. The blending conditions as well as the properties of the polymer and monomer are chosen such that after evaporation of the solvent a solid film is formed. In general this allows that upon patterned exposure with UV light a latent image is formed. The latent image can be developed into a surface profile by heating where polymerization and diffusion occur simultaneously, thus increasing the materials volume at the exposed area or vice versa which results in a surface deformation. In a final processing step the sample is fully polymerized by applying a flood exposure at elevated temperatures. The surface relief structures created by such a photo-embossing process are typically in a 1-200 μm range, preferably the relief structures have a height between 2 and 100 μm, or between 4 and 60 μm.

The photo-embossing process is not to be confused with conventional photo-lithography. In the conventional photolithography process, a photoreactive resin (photoresist) is applied as a film on substrate. The film is locally exposed by electromagnetic radiation and as a result a difference in solubility between exposed and non-exposed areas is created. To create the relief structures the soluble areas are removed by using a solvent, followed by etching of the surface of the substrate.

In photo-embossing the surface relief structure is formed by a change in chemical potential between exposed and non-exposed areas and the resulting diffusion of monomer.

A weakness of the photo-embossing process known in the art is that the resulting relief structure has a rather low aspect ratio. The aspect ratio (AR) is defined as the ratio between the relief height and structure width. As a result of which the optical function or other functionality that is aimed at is less optimal.

There is a need for obtaining a polymeric relief structure having an improved AR resulting in better (physical) functionalities and other properties.

It has now been found that the presence of a radical scavenger influences the AR of the polymeric relief structure in an unexpected way. It has been unexpectedly found that the AR can be improved with the application of certain amounts of radical scavengers. Both the absence of a radical scavenger and the presence of a too large amount of radical scavenger generate relief structures that have a low AR.

The present invention relates to a process for the preparation of a polymeric relief structure comprising the steps
a) coating a substrate with a coating composition comprising one or more radiation-sensitive ingredients,
b) locally treating the coated substrate with electromagnetic radiation having a periodic or random radiation-intensity pattern, forming a latent image,
c) polymerizing and/or crosslinking the resulting coated substrate, wherein the coating composition comprises one or more organic radical scavengers in an amount sufficient to inhibit/retard substantial polymerization in the non-treated areas of the coated substrate, and low enough to allow polymerization and/or crosslinking in the treated areas in step c, with the proviso that the amount of oxygen present in the coating composition is less then the equilibrium amount of oxygen present when the coating composition is in contact with air.

Another embodiment of the present invention is a process for the preparation of a polymeric relief structure comprising the steps
a) coating a substrate with a coating composition comprising one or more radiation-sensitive ingredients,
b) locally treating the coated substrate with electromagnetic radiation having a periodic or random radiation-intensity pattern, forming a latent image,
c) polymerizing and/or crosslinking the resulting coated substrate, wherein the coating composition comprises a blend of at least one polymer, at least one monomer, a photoinitiator, optionally a solvent and one or more organic radical scavengers in an amount between 0.5 and 20 wt % (relative to the blend of polymer(s), monomer(s) and initiator(s)).

A radical scavenger is a compound that reacts with radicals. This can be done in at least two different ways. The effect of these reactions is that the radical scavengers suppress the polymerization of monomers. These scavengers act by reacting with the initiating and propagating radicals and converting them to either nonradical species or radicals of reactivity too low to undergo propagation. Such radical scavengers are classified according to their effectiveness. Inhibitors stop every radical, and polymerization is completely halted until they are consumed. Retarders are less efficient and stop only a portion of the radicals. In this case, polymerization occurs, but at a slower rate and lower polymer molecular weight.

Oxygen is known to be an effective radical scavenger. The concentration of oxygen in the environment influences the AR. It is found that photopolymer processed under an inert atmosphere (100% nitrogen) produces lower AR structures than photopolymer processed under air (21 % v oxygen, 79% nitrogen). It has been found that the optimum content of oxygen is also determined by the amount of radiation to form the latent image. For a higher amount of radiation, the optimum content of oxygen also becomes higher. Increasing the oxygen content of the environment above the concentration present in air can result in even higher structures. In one embodiment of the present invention, the amount of oxygen in the atmosphere above the coating composition contains preferably between 30 and 100 vol % oxygen, more preferably between 40 and 80 vol % of oxygen.

It has been found, that addition of organic radical scavengers to a composition, which is in equilibrium with air, lowers the AR. Organic radical scavengers are radical scavengers having at least one or more organic groups. Surprisingly, addition of organic radical scavengers does have a positive effect on the AR especially when a reduced level of oxygen is present in the composition. If no oxygen or low amounts of oxygen are present, organic radical scavengers can be added to the photopolymer to increase the AR of the structures. The addition of organic radical scavengers in the process of the invention (under reduced oxygen levels) generates structures that have higher AR ratios then structures made without the organic scavengers. Examples of suitable organic radical scavengers are phenols, quinones, captodative olefins, nitrones, nitro compounds, nitroso compounds and transition metal complexes.

The organic radical scavengers are preferably present in an amount ranging from 0.5-20 wt %, more preferably between 1-18%, even more preferable 2-16 wt %, most preferably between 6 and 14 wt % (relative to the blend comprising the polymer(s), monomer(s) and an initiator(s)).

It is surprising that adding an organic radical scavenger results in approximately twice as high structures when compared to a gaseous radical scavenger. For example the maximum AR of photo-embossed structures for a 40 μm linemask with fill factor of 0.5 under optimized oxygen concentrations is approximately 0.199. The maximum AR of photo-embossed structures for a 40 μm linemask with a fill factor of 0.5 under optimized t-butylhydroquinone is approximately 0.396.

A linemask with fillfactor 0.5 is a mask comprising parallel lines, wherein 50% of the surface is non-transparant. T-butylhydroquinone is here the organic radical scavenger.

Organic radical scavengers are known to the skilled man in the art. They may also be known as inhibitors or retarders. Non limiting examples of suitable organic radical scavengers are phenols, (like for example hydroquinone, monomethylhydroquinone, 3,5-t-butylcatechol, t-butyl hydroquinone, α-naphtol, 2-nitro-α-naphtol, β-naphtol, 1-nitro-β-naphtol, phenol, 2,4-dinitrophenol, o-nitrophenol, m-nitrophenol, p-nitrophenol, hydroquinone mono methyl, di-tert-butylhydroquinone, tertiairbutylhydroquine, tetrafluorohydroquinone, trimethylhydroquinone); Quinones, (like for example p-benzoquinone, chloro-p-benzoquinone, 2,5-dichloro-p-benzoquinone, 2,6-dichloro-p-benzoquinone, 2,3-dimethyl-p-benzoquinone, 2,5-dimethyl-p-benzoquinone, methoxy-p-benzoq uinone, methyl-p-benzoquinone, tetrabromo-p-benzoquinone, tetrachloro-p-benzoquinone, tetra-iodo-p-benzoquinone, tetramethyl-p-benzoquinone, trichloro-p-benzoquinone, trimethyl-p-benzoquinone); Nitrones, nitro- and nitroso-compounds (like for example o-dinitrobenzene, m-dinitrobenzene, p-dinitrobenzene, nitrobenzene, nitro-d5-benzene, p-nitro-chlorobenzene, 1,3,5-trinitrobenzene, p-nitrobenzoic acid, nitro-diphenyl, diphenylpicrylhydrzyl, dinitrodurene, 1,5-dinitro-naphthalene, picramide, picric acid, picryl chloride, 2,4-dinitrotoluene, o-nitrotoluene, m-nitrotoluene, p-nitrotoluene, 1,3,5-trinitrotoluene); Captodative olefins: stable radicals (like for example acetophenone, aniline, bromobenzene, diazoaminobenzene, benzoic acid, benzoic acid ethyl ester, benzophenone, benzoyl chloride, diphenyl, diphenyl amine, durene, fluorine, triphenylmethane, naphthalene, phenanthrene, stilbene, sulfur, toluene, p-bromotoluene, tolunitrile, p-xylene); 1,1 diphenyl-2-picrylhydrazyl (DPPH).

As a result, relief structures with an enhanced relief aspect ratio (the improvement typically showing an increase of a factor 2).

The coating used in step a) of the present process comprises one or more radiation sensitive ingredients, which in general are C═C unsaturated monomers, polymerizable via electromagnetic radiation. These ingredients can be used as such, but also in the form of a solution.

The coating may be applied onto the substrate by any process known in the art of (wet) coating deposition. Examples of suitable processes are spin coating, dip coating, spray coating, flow coating, meniscus coating, doctor's blading, capillary coating, and roll coating.

Typically, the radiation sensitive ingredients are mixed, preferably with at least one solvent and, optionally, crosslinking initiator to prepare a mixture that is suitable for application to the substrate using the chosen method of application.

In principle, a wide variety of solvents may be used. However, the combination of the solvents and all other materials present in the mixture should preferentially form stable suspensions or solutions.

Preferably the solvent used is evaporated after applying the coating onto the substrate. In the process according to the invention, optionally the coating may after application to the substrate be heated or treated in vacuum to aid evaporation of the solvent.

Examples of solvents that are suitable are 1,4-dioxane, acetone, acetonitrile, chloroform, chlorophenol, cyclohexane, cyclohexanone, cyclopentanone, dichloromethane, diethyl acetate, diethyl ketone, dimethyl carbonate, dimethylformamide, dimethylsulphoxide, ethanol, ethyl acetate, m-cresol, mono- and di-alkyl substituted glycols, N,N-dimethylacetamide, p-chlorophenol, 1,2-propanediol, 1-pentanol, 1-propanol, 2-hexanone, 2-methoxyethanol, 2-methyl-2-propanol, 2-octanone, 2-propanol, 3-pentanone, 4-methyl-2-pentanone, hexafluoroisopropanol, methanol, methyl acetate, butyl acetate, methyl acetoacetate, methyl ethyl ketone, methyl propyl ketone, n-methylpyrrolidone-2, n-pentyl acetate, phenol, tetrafluoro-n-propanol, tetrafluoroisopropanol, tetrahydrofuran, toluene, xylene and water. Alcohol, ketone and ester based solvents may also be used, although the solubility of acrylates may become an issue with high molecular weight alcohols. Halogenated solvents (such as dichloromethane and chloroform) and hydrocarbons (such as hexanes and cyclohexanes), are suitable.

The mixtures preferably contain a polymeric material. In fact each polymer can be used that forms a homogenous mixture with the other components. Well-studied polymers are polymethylmethacrylate, polymethylacrylate, polystyrene, polybenzylmethacrylate, polyisobornylmethacrylate. But also many other polymers may be applied as well. The mixture also contains a monomeric compound, being a compound of relatively low molecular weight, i.e. smaller than 1500 daltons, that upon contact with reactive particles, i.e. free radicals or cationic particles, polymerize. In a preferred embodiment the monomer or one of the monomers of a monomer mixture contains more than one polymerizing group such that upon polymerization a polymer network is formed. Further in the preferred embodiment the monomers are molecules containing reactive group of the following classes: vinyl, acrylate, methacrylate, epoxide, vinylether, oxetane or thiol-ene. The mixture also contains a photosensitive component being the compound that upon exposure to actinic radiation generates the reactive particle, i.e. the free-radicals or cationic particles.

Examples of monomers suitable for use as polymerizing ingredient and having at least two crosslinkable groups per molecule include monomers containing (meth)acryloyl groups such as trimethylolpropane tri(meth)acrylate, pentaerythritol(meth)acrylate, ethylene glycol di(meth)acrylate, tetraethylene glycol di(meth)acrylate, polyethylene glycol di(meth)acrylate, 1,4-butanediol di(meth)acrylate, 1,6-hexanediol di(meth)acrylate, neopentyl glycol di(meth)acrylate, polybutanediol di(meth)acrylate, tripropyleneglycol di(meth)acrylate, glycerol tri(meth)acrylate, phosphoric acid mono- and di(meth)acrylates, C₇-C₂₀ alkyl di(meth)acrylates, trimethylolpropanetrioxyethyl(meth)acrylate, tris(2-hydroxyethyl)isocyanurate tri(meth)acrylate, tris(2-hydroxyethyl)isocyanurate di(meth)acrylate, pentaerythritol tri(meth)acrylate, pentaerythritol tetra(meth)acrylate, dipentaerythritol monohydroxy pentacrylate, dipentaerythritol hexacrylate, tricyclodecane diyl dimethyl di(meth)acrylate and alkoxylated versions, preferably ethoxylated and/or propoxylated, of any of the preceding monomers, and also di(meth)acrylate of a diol which is an ethylene oxide or propylene oxide adduct to bisphenol A, di(meth)acrylate of a diol which is an ethylene oxide or propylene oxide adduct to hydrogenated bisphenol A, epoxy(meth)acrylate which is a (meth)acrylate adduct to bisphenol A of diglycidyl ether, diacrylate of polyoxyalkylated bisphenol A, and triethylene glycol divinyl ether, adduct of hydroxyethyl acrylate, isophorone diisocyanate and hydroxyethyl acrylate (HIH), adduct of hydroxyethyl acrylate, toluene diisocyanate and hydroxyethyl acrylate (HTH), and amide ester acrylate.

Examples of suitable monomers having only one crosslinking group per molecule include monomers containing a vinyl group, such as N-vinyl pyrrolidone, N-vinyl caprolactam, vinyl imidazole, vinyl pyridine; isobornyl(meth)acrylate, bornyl(meth)acrylate, tricyclodecanyl(meth)acrylate, dicyclopentanyl(meth)acrylate, dicyclopentenyl(meth)acrylate, cyclohexyl(meth)acrylate, benzyl(meth)acrylate, 4-butylcyclohexyl(meth)acrylate, acryloyl morpholine, (meth)acrylic acid, 2-hydroxyethyl(meth)acrylate, 2-hydroxypropyl(meth)acrylate, 2-hydroxybutyl(meth)acrylate, methyl(meth)acrylate, ethyl(meth)acrylate, propyl(meth)acrylate, isopropyl(meth)acrylate, butyl(meth)acrylate, amyl(meth)acrylate, isobutyl(meth)acrylate, t-butyl(meth)acrylate, pentyl(meth)acrylate, caprolactone acrylate, isoamyl(meth)acrylate, hexyl(meth)acrylate, heptyl(meth)acrylate, octyl(meth)acrylate, isooctyl(meth)acrylate, 2-ethylhexyl(meth)acrylate, nonyl(meth)acrylate, decyl(meth)acrylate, isodecyl(meth)acrylate, tridecyl(meth)acrylate, undecyl(meth)acrylate, lauryl(meth)acrylate, stearyl(meth)acrylate, isostearyl(meth)acrylate, tetrahydrofurfuryl(meth)acrylate, butoxyethyl(meth)acrylate, ethoxydiethylene glycol(meth)acrylate, benzyl(meth)acrylate, phenoxyethyl(meth)acrylate, polyethylene glycol mono(meth)acrylate, polypropylene glycol mono(meth)acrylate, methoxyethylene glycol(meth)acrylate, ethoxyethyl(meth)acrylate, methoxypolyethylene glycol(meth)acrylate, methoxypolypropylene glycol(meth)acrylate, diacetone(meth)acrylamide, beta-carboxyethyl(meth)acrylate, phthalic acid(meth)acrylate, isobutoxymethyl(meth)acrylamide, N,N-dimethyl(meth)acrylamide, t-octyl(meth)acrylamide, dimethylaminoethyl(meth)acrylate, diethylaminoethyl(meth)acrylate, butylcarbamylethyl(meth)acrylate, n-isopropyl(meth)acrylamide fluorinated(meth)acrylate, 7-amino-3,7-dimethyloctyl(meth)acrylate, N,N-diethyl(meth)acrylamide, N,N-dimethylaminopropyl(meth)acrylamide, hydroxybutyl vinyl ether, lauryl vinyl ether, cetyl vinyl ether, 2-ethylhexyl vinyl ether; and compounds represented by the following formula (I)

CH₂═C(R⁶)—COO(R⁷O)ₘ—R⁸ (I)

wherein R⁶ is a hydrogen atom or a methyl group; R⁷ is an alkylene group containing 2 to 8, preferably 2 to 5 carbon atoms; and m is an integer from 0 to 12, and preferably from 1 to 8; R⁸ is a hydrogen atom or an alkyl group containing 1 to 12, preferably 1 to 9, carbon atoms; or, R⁸ is a tetrahydrofuran group-comprising alkyl group with 4-20 carbon atoms, optionally substituted with alkyl groups with 1-2 carbon atoms; or R⁸ is a dioxane group-comprising alkyl group with 4-20 carbon atoms, optionally substituted with methyl groups; or R⁸ is an aromatic group, optionally substituted with C₁-C₁₂ alkyl group, preferably a C₈-C₉ alkyl group, and alkoxylated aliphatic monofunctional monomers, such as ethoxylated isodecyl(meth)acrylate, ethoxylated lauryl(meth)acrylate, and the like.

Oligomers suitable for use as a radiation sentitive ingredient are for example aromatic or aliphatic urethane acrylates or oligomers based on phenolic resins (ex. bisphenol epoxy diacrylates), and any of the above oligomers chain extended with ethoxylates. Urethane oligomers may for example be based on a polyol backbone, for example polyether polyols, polyester polyols, polycarbonate polyols, polycaprolactone polyols, acrylic polyols, and the like. These polyols may be used either individually or in combinations of two or more. There are no specific limitations to the manner of polymerization of the structural units in these polyols. Any of random polymerization, block polymerization, or graft polymerization is acceptable. Examples of suitable polyols, polyisocyanates and hydroxylgroup-containing (meth)acrylates for the formation of urethane oligomers are disclosed in WO 00/18696, which is incorporated herein by reference.

Combinations of compounds that together may result in the formation of a crosslinked phase and thus in combination are suitable to be used as the reactive diluent are for example carboxylic acids and/or carboxylic anhydrides combined with epoxies, acids combined with hydroxy compounds, especially 2-hydroxyalkylamides, amines combined with isocyanates, for example blocked isocyanate, uretdion or carbodiimide, epoxies combined with amines or with dicyandiamides, hydrazinamides combined with isocyanates, hydroxy compounds combined with isocyanates, for example blocked isocyanate, uretdion or carbodiimide, hydroxy compounds combined with anhydrides, hydroxy compounds combined with (etherified) methylolamide (“amino-resins”), thiols combined with isocyanates, thiols combined with acrylates or other vinylic species (optionally radical initiated), acetoacetate combined with acrylates, and when cationic crosslinking is used epoxy compounds with epoxy or hydroxy compounds.

Further possible compounds that may be used as a radiation sensitive ingredient are moisture curable isocyanates, moisture curable mixtures of alkoxy/acyloxy-silanes, alkoxy titanates, alkoxy zirconates, or urea-, urea/melamine-, melamine-formaldehyde or phenol-formaldehyde (resol, novolac types), or radical curable (peroxide- or photo-initiated) ethylenically unsaturated mono- and polyfunctional monomers and polymers, e.g. acrylates, methacrylates, maleate/vinyl ether), or radical curable (peroxide- or photo-initiated) unsaturated e.g. maleic or fumaric, polyesters in styrene and/or in methacrylates.

Preferably, the applied coating also comprises a polymer, preferably of the same nature as the polymer resulting from the crosslinking of the radiation sensitive ingredients. Preferably, this polymer has a weight-averaged molecular weight (Mw) of at least 20,000 g/mol.

The polymer, when used in the coating step a), preferably has a glass transition temperature of at least 300 K. Preferably, the polymer in the coating used in step a) is dissolved in the monomer(s), present in the radiation sensitive coating of step a) or in the solvent used in the coating of step a) of the process of the present invention.

A wide variety of substrates may be used as a substrate in the process according to the invention. Suitable substrates are for example flat or curved, rigid or flexible polymeric substrates, including films of for example polycarbonate, polyester, polyvinyl acetate, polyvinyl pyrollidone, polyvinyl chloride, polyimide, polyethylene naphthalate, polytetrafluoro-ethylene, nylon, polynorbornene or amorphous solids, for example glass or crystalline materials, such as for example silicon or gallium arsenide. Metallic substrates may also be used. Preferred substrates for use in display applications are for example glass, polynorbornene, polyethersulfone, polyethyleneterephtalate, polyimide, cellulose triacetate, polycarbonate and polyethylenenaphthalate.

An initiator may be present in the coating to initiate the crosslinking reaction. The amount of initiator may vary between wide ranges. A suitable amount of initiator is for example between above 0 and 10 wt % with respect to total weight of the compounds that take part in the crosslinking reaction.

When UV-crosslinking is used to initiate crosslinking, the mixture preferably comprises a UV-photo-initiator. A photo-initiator is capable of initiating a crosslinking reaction upon absorption of light; thus, UV-photo-initiators absorb light in the Ultra-Violet region of the spectrum. Any known UV-photo-initiators may be used in the process according to the invention.

Preferably the polymerization initiator comprises a mixture of a photo initiator and a thermal initiator.

Any cross-linking method that may cause the coating to polymerize and/or crosslink so that a final coating is formed is suitable to be used in the process according to the invention. Suitable ways to initiate crosslinking are for example electron beam radiation, electromagnetic radiation (UV, Visible and Near IR), thermally and by adding moisture, in case moisture-curable compounds are used. In a preferred embodiment crosslinking is achieved by UV-radiation. The UV-crosslinking may take place through a free radical mechanism or by a cationic mechanism, or a combination thereof. In another preferred embodiment the crosslinking is achieved thermally.

In step b) of the process of the present invention the coated substrate resulting form process step a) is locally treated with electromagnetic radiation having a periodic or latent radiation intensity pattering as a result of which a latent image is formed. In one preferred embodiment, this treatment is performed using UV-light in combination with a mask. In another preferred embodiment, this treatment is performed by the use of light interference/holography. Still another embodiment is by the use of electron beam lithography.

The essential feature of the present invention is the use of a radical scavenger in an appropriate amount to exactly tune the rate of polymerization or inhibition time or both for generation relief structure with a high aspect ratio.

The conditions under which the process steps a)-d) have to be performed, are as such known in the art of radiation polymerization. As temperatures for said process steps preferably a temperature of between 175 and 375 K is used for step b), and preferably a temperature of between 300 and 575 K is used for step c).

It has been found that the AR of the polymeric relief structure can be further improved by addition of a higher dose of UV exposure. The optimum amount of radical scavenger generally increases when a higher dose of exposure is used. The combination of a higher exposure dose and a higher radical scavenger concentration has resulted in a further improvement of the process of the present invention.

The polymeric relief structures of the present invention have an improved aspect ratio. The aspect ratio (AR, being the ratio between the relief height and structure width, both in μm) of the reliefs of the invention is in general at least 0.075, and more preferably at least 0.12; even more preferably, the AR is at least 0.2.

The polymeric relief structures of the present invention are applicable in optical components. Examples thereof are quarter wave films and wire grid polarizes for applications in, e.g. LCD's or LED's. Also moth eye or lotus flower structures for self-cleaning surfaces are attainable herewith. Another and preferred embodiment is the use of the polymeric relief structure as a master for replication purposes in organic or inorganic matter. Other applications comprise Anti reflective/anti glare layers; vertically aligned displays (where photo-embossing is used to create the protrusions for alignment of the LCs); Microlenses; Reflectors, transflectors; polarizers; protein arrays, DNA arrays and microcontact printing

The invention is further elucidated with the following Examples and comparative experiments, which are not meant to restrict the invention.

### COMPARATIVE EXAMPLE 1

### Air

The photopolymer consisted of a mixture containing: 50 wt % of polymer, polybenzylmethacrylate (Mw=70 kg/mol), and 50 wt % of a multifunctional monomer, di-penta erythritol tetraacrylate. To the photopolymer was added 5 wt % of a photo-initiator (Irgacure 819). The mixture of photopolymer and photoinitiator was dissolved in 50 wt % of a 1:1 mixture of propylene glycol methyl ether acetate and ethoxypropylacetate.

The dissolved mixture was spincoated on a glass substrate. After spincoating, the glass substrate with the thin film was heated to 80° C. for 20 minutes to remove residual traces of solvent resulting in a film of approximately 16 μm thickness. A photo mask with a grating (pitch=40 μm) was used in direct contact with the solid polymer film. An exposure to ultra-violet light (Oriel deep UV lamp, model type 66902, E=0.128 J/cm²) was performed. After exposure to UV light, the sample was heated to 110° C. (20 minutes) to generate the relief structures. Finally a flood exposure was performed with a UV lamp (E=0.8 J/cm²) at 110° C. to fix the sample.

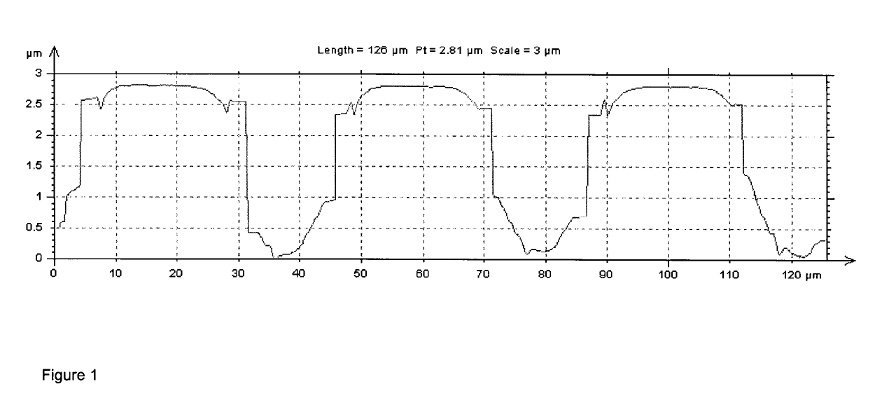

The formed relief structure was analyzed with an optical profilometer (FIG. 1). The relief structure had a height of approximately 2.6 μm and an AR of 0.14

### COMPARATIVE EXAMPLE 2

### Nitrogen

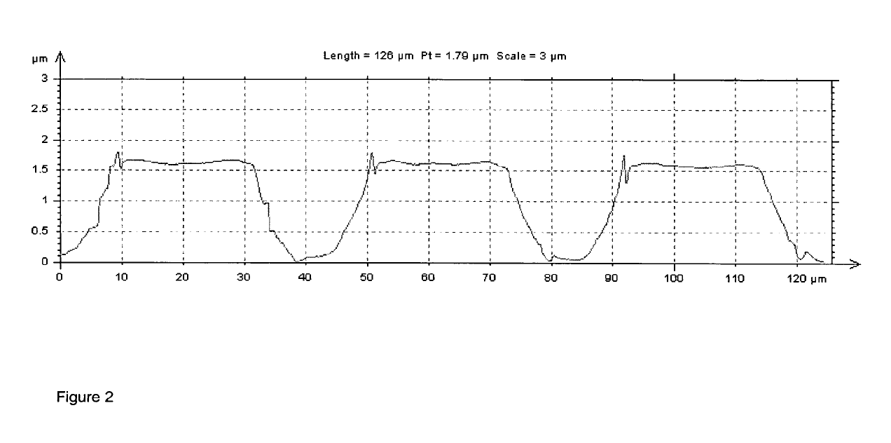

The experimental conditions of comparative example 1 were used. Both during the illumination and during the heating step, the film kept in a nitrogen atmosphere. The height of the structures was measured using an optical profilometer (FIG. 2). The relief structure had a height of approximately 1.5 μm and an AR of 0.08.

Comparative example 1 and comparative example 2 illustrate that invironmental oxygen has a large influence on the generation of relief structures.

### COMPARATIVE EXAMPLE 3

### Air+T-Butyl Hydroquinone

The experimental conditions of comparative example 1 were used. Two weight percent of T-butyl Hydroquinone was added to dry photopolymer before processing. Both during the illumination and during the heating step, the film was kept in an air atmosphere. When measuring the structure height with an optical profilometer no structures could be detected. Comparative example 3 shows that combining environmental oxygen with an added radical scavenger results in no structure formation.

### EXAMPLE 1

### Oxygen

The experimental conditions of comparative example 1 were used. Both during the illumination and during the heating step, the film was exposed to a controlled environment with respect to oxygen content. The total exposure dose was varied between 0.01 and 3.1 J/cm² to find the optimum exposure dose for each oxygen concentration. The AR of the structures was determined using an optical profilometer and the results are shown below in table 1.

The results in the table above illustrate that the optimum oxygen content is between 30-100 vol % when high exposure doses of at least 0.13 J/cm² are being applied

TABLE 1

| Fraction | Exposure Dose [J/cm²] | | | | | | |
|---|---|---|---|---|---|---|---|
| O2 [—] | 3.10 | 1.92 | 0.75 | 0.34 | 0.13 | 0.02 | 0.01 |
| 0.00 | 0.028 | 0.027 | 0.023 | 0.020 | 0.015 | 0.008 | 0.004 |
| 0.04 | 0.027 | 0.027 | 0.025 | 0.023 | 0.021 | 0.030 | 0.030 |
| 0.08 | 0.030 | 0.031 | 0.035 | 0.044 | 0.071 | 0.095 | 0.052 |
| 0.13 | 0.038 | 0.040 | 0.048 | 0.068 | 0.117 | 0.143 | 0.071 |
| 0.17 | 0.038 | 0.043 | 0.061 | 0.103 | 0.138 | 0.109 | 0.019 |
| 0.21 | 0.040 | 0.048 | 0.074 | 0.110 | 0.137 | 0.101 | 0.024 |
| 0.37 | 0.048 | 0.055 | 0.095 | 0.140 | 0.175 | 0.099 | 0.028 |
| 0.53 | 0.065 | 0.087 | 0.147 | 0.183 | 0.169 | 0.039 | 0.014 |
| 0.68 | 0.087 | 0.132 | 0.199 | 0.185 | 0.059 | 0.013 | 0.001 |
| 0.84 | 0.064 | 0.078 | 0.089 | 0.067 | 0.032 | 0.010 | 0.004 |
| 1.00 | 0.104 | 0.140 | 0.166 | 0.072 | 0.021 | 0.003 | 0.001 |

### EXAMPLE 2

### T-Butyl Hydroquinone

Polybenzylmethacrylate (M_{w} 70 kg mol⁻¹) was used as a polymeric binder, dipentaerythritol penta/hexa acrylate as a multifunctional monomer and Irgacure 819 as a photoinitiator. As a solvent a 50/50 wt % mixture of Ethoxypropylacetate and Propyleneglycolmethyletheracetate was used. To prepare the photopolymer solution, the multifunctional monomer and the solvent were mixed in a weight ratio of 1:2. This solution was added to an radical scavenger removing column to remove the 500 ppm of MEHQ present in the monomer. Subsequently the monomer/solvent mixture was mixed with the polymer and photo-initiator in a weight ratio of respectively 30:10:1. As a radical scavenger T-butyl Hydroquinone (TBHQ) was used, which was added in different concentration to the photopolymer solution.

The photopolymer solution was spincoated on glass substrates (5×5 xm) at 800 rpm. To remove the solvent the sample was dried at 80° C. for 20 minutes after which it was cooled to room temperature. The film was exposed to a collimated UV-light source (Oriel deep UV lamp, model type 66902) using a contact mask with different pitches; 10, 15, 20, 30 and 40 μm. The total exposure dose was varied between 0.6, 1.35 and 2.38 J/cm². Afterwards the film was heated to 110° C. (20 min.) to generate the relief structures. Both during the illumination and during the heating step, the film was exposed to nitrogen. Finally a flood exposure was performed with a UV lamp (E=0.8 J/cm²) at 110° C. to fix the sample.

The AR were determined using a mechanical profilometer and the results are shown in tables 2-4 below. Table 2 shows the results of the samples that where exposed to 0.6 J/cm², table 3 shows the results of the samples that exposed to 1.35 J/cm² and table 4 shows the results of the samples that where exposed to 2.38 J/cm².

TABLE 2

| Amount of TBHQ | | | | | |
|---|---|---|---|---|---|
| added to solid | | | | | |
| photopolymer | Period of surface relief [μm] | | | | |
| [w/w %] | 40 | 30 | 20 | 15 | 10 |
| 0 | 0.039 | 0.049 | 0.051 | 0.045 | 0.032 |
| 1.9 | 0.125 | 0.154 | 0.17 | 0.138 | 0.087 |
| 3.8 | 0.193 | 0.217 | 0.196 | 0.153 | 0.079 |
| 7.2 | 0.249 | 0.263 | 0.223 | 0.162 | 0.077 |
| 8.9 | 0.248 | 0.267 | 0.217 | 0.153 | 0.077 |
| 12.0 | 0.243 | 0.283 | 0.244 | 0.198 | 0.091 |
| 12.8 | 0.192 | 0.193 | 0.159 | 0.133 | 0.08 |
| 14.2 | 0.185 | 0.180 | 0.133 | 0.091 | 0.051 |
| 14.9 | 0.129 | 0.139 | 0.117 | 0.101 | 0.066 |
| 16.3 | 0.117 | 0.114 | 0.092 | 0.075 | 0.049 |
| 19 | 0.054 | 0.054 | 0.044 | 0.037 | 0.021 |
| 21.5 | 0.089 | 0.087 | 0.068 | 0.052 | 0.043 |

TABLE 3

| Amount of TBHQ | | | | | |
|---|---|---|---|---|---|
| added to solid | | | | | |
| photopolymer | Period of surface relief [μm] | | | | |
| [w/w %] | 40 | 30 | 20 | 15 | 10 |
| 0 | 0.04 | 0.049 | 0.053 | 0.042 | 0.028 |
| 1.9 | 0.070 | 0.099 | 0.119 | 0.098 | 0.079 |
| 3.8 | 0.161 | 0.203 | 0.191 | 0.152 | 0.114 |
| 7.2 | 0.276 | 0.318 | 0.276 | 0.209 | 0.114 |
| 8.9 | 0.284 | 0.308 | 0.262 | 0.21 | 0.132 |
| 12.0 | 0.341 | 0.356 | 0.297 | 0.248 | 0.163 |
| 12.8 | 0.329 | 0.344 | 0.263 | 0.227 | 0.145 |
| 14.2 | 0.302 | 0.272 | 0.189 | 0.148 | 0.104 |
| 14.9 | 0.309 | 0.321 | 0.284 | 0.202 | 0.112 |
| 16.3 | 0.287 | 0.335 | 0.275 | 0.198 | 0.090 |
| 19 | 0.123 | 0.120 | 0.087 | 0.059 | 0.038 |
| 21.5 | 0.157 | 0.141 | 0.112 | 0.092 | 0.051 |

TABLE 4

| Amount of TBHQ | | | | | |
|---|---|---|---|---|---|
| added to solid | | | | | |
| photopolymer | Period of surface relief [μm] | | | | |
| [w/w %] | 40 | 30 | 20 | 15 | 10 |
| 0 | 0.038 | 0.049 | 0.048 | 0.038 | 0.026 |
| 1.9 | 0.063 | 0.080 | 0.081 | 0.069 | 0.053 |
| 3.8 | 0.114 | 0.132 | 0.147 | 0.136 | 0.105 |
| 7.2 | 0.259 | 0.287 | 0.270 | 0.197 | 0.127 |
| 8.9 | 0.257 | 0.314 | 0.285 | 0.222 | 0.143 |
| 12.0 | 0.312 | 0.33 | 0.302 | 0.249 | 0.18 |
| 12.8 | 0.304 | 0.324 | 0.277 | 0.239 | 0.17 |
| 14.2 | 0.296 | 0.284 | 0.207 | 0.168 | 0.116 |
| 14.9 | 0.342 | 0.325 | 0.266 | 0.219 | 0.138 |
| 16.3 | 0.396 | 0.431 | 0.359 | 0.253 | 0.132 |
| 19 | 0.199 | 0.214 | 0.131 | 0.084 | 0.039 |
| 21.5 | 0.275 | 0.288 | 0.215 | 0.155 | 0.122 |

The results in Table 2,3 and 4 show that adding T-butyl Hydroquinone to the coating composition results in increased AR in the absence of environmental oxygen.

### EXAMPLE 3

### TriMethyl Hydroquinone

The experimental conditions of example 2 were used. As a radical scavenger Tri-Methyl Hydroquinone (TMHQ) was used, which was added in different concentration to the photopolymer solution. The total exposure dose was 2.7 J/cm² (which was found to be the optimum exposure dose in preliminary tests). The height of the structures was measured using an optical profilometer and the results are shown below in table 5.

TABLE 5

| Amount of TBHQ | | | |
|---|---|---|---|
| added to solid | | | |
| photopolymer | Period of surface relief [μm] | | |
| [w/w %] | 40 | 30 | 20 |
| 1.8 | 0.130 | 0.15 | 0.15 |
| 3.5 | 0.199 | 0.241 | 0.234 |
| 5.1 | 0.230 | 0.267 | 0.270 |
| 8.2 | 0.295 | 0.367 | 0.326 |
| 11.1 | 0.223 | 0.247 | 0.198 |

### EXAMPLE 4

### TetraFluoro Hydroquinone

The experimental conditions of example 2 were used. As a radical scavenger TetraFluoro Hydroquinone (Aldrich) was used, which was added in different concentration to the photopolymer solution. The total exposure dose was 0.330 J/cm² (which was found to be the optimum exposure dose in preliminary tests). The height of the structures was measured using an optical profilometer and the results are shown table 6.

TABLE 6

| Amount of TFHQ | | | |
|---|---|---|---|
| added to solid | | | |
| photopolymer | Period of surface relief [μm] | | |
| [w/w %] | 40 | 30 | 20 |
| 2.1 | 0.078 | 0.109 | 0.093 |
| 4.1 | 0.114 | 0.148 | 0.165 |
| 6.0 | 0.197 | 0.259 | 0.274 |
| 9.7 | 0.273 | 0.279 | 0.316 |
| 13.0 | 0.223 | 0.247 | 0.256 |
| 14.6 | 0.178 | 0.174 | 0.140 |
| 19.0 | 0.150 | 0.150 | 0.132 |
| 20.4 | 0.178 | 0.158 | 0.147 |

1. Process for the preparation of a polymeric relief structure comprising the steps
a) coating a substrate with a coating composition comprising one or more radiation-sensitive ingredients,
b) locally treating the coated substrate with electromagnetic radiation having a periodic or random radiation-intensity pattern, forming a latent image,
c) polymerizing and/or crosslinking the resulting coated substrate, wherein the coating composition comprises one or more organic radical scavengers in an amount sufficient to inhibit/retard substantial polymerization in the non-treated areas of the coated substrate, and low enough to allow polymerization and/or crosslinking in the treated areas in step c, with the proviso that the amount of oxygen present in the coating composition is not equal to the equilibrium amount of oxygen present when the coating composition is in contact with air.

2. Process for the preparation of a polymeric relief structure comprising the steps
a) coating a substrate with a coating composition comprising one or more radiation-sensitive ingredients,
b) locally treating the coated substrate with electromagnetic radiation having a periodic or random radiation-intensity pattern, forming a latent image.
c) polymerizing and/or crosslinking the resulting coated substrate, wherein the coating composition comprises a blend of at least one polymer, at least one monomer, a photoinitiator, optionally a solvent and one or more organic radical scavengers in an amount between 0.5 and 20 wt % (relative to the blend of polymer(s), monomer(s) and initiator(s)).

3. Process according to claim 1, wherein step b) and c) are combined.

4. Process according to claim 1, wherein the coating composition comprises a blend of at least one polymer, at least one monomer, a photoinitiator and optionally a solvent.

5. Process according to claim 2, wherein the solvent is removed between step a and b.

6. Process according to claim 1, wherein an cationic scavenger is present.

7. Process according to claim 1, wherein an organic radical scavenger is present.

8. Process according to claim 1, wherein a radical scavenger is present selected from the group consisting of phenols, quinones, captodative olefins, nitrones, nitro compounds, nitroso compounds and transition metal complexes.

9. Process according to claim 1, wherein the amount of organic radical scavenger in the coating composition is between 0.5 and 20 wt % (relative to the blend polymer(s), monomer(s) and initiator(s))

10. Process according to claim 1, wherein the amount of radical scavenger in the coating composition is between 2 and 18 wt %, relative to the blend comprising the polymer(s), monomer(s) and an initiator(s).
